(19) United States
(12) Patent Application Publication
(10) Pub. No.: US 2012/0127376 A1
(43) Pub. Date: May 24, 2012

(54) DISPLAY DEVICE AND VIDEO INFORMATION PROCESSINSG DEVICE USING THE SAME

(75) Inventor: Noriyuki Shikina, Ichihara-shi (JP)

(73) Assignee: CANON KABUSHIKI KAISHA, Tokyo (JP)

(21) Appl. No.: 13/294,076

(22) Filed: Nov. 10, 2011

(30) Foreign Application Priority Data
Nov. 24, 2010 (JP) 2010-261605

(51) Int. Cl. H04N 5/70; G02B 27/12

(52) U.S. Cl. 348/800; 359/619; 348/E05.135

(57) ABSTRACT

A display device including a light emitting element array composed of a plurality of light emitting elements includes a micro lens array composed of a plurality of micro lenses provided on the light emission surface side of the light emitting element array and a light shielding member provided on the light emission surface side more than the micro lens array. The light shielding member includes a light shielding member in which a light absorption wall and a medium arranged alternately along the light emission surface, wherein the light absorption rate of the medium is lower than that of the light absorption wall.

### BACKGROUND OF THE INVENTION

1. Field of the Invention

The present invention relates to a display device, and more particularly to a display device using an organic electro-luminescence (EL) element and a video information processing device using the organic EL element.

2. Description of the Related Art

A display device using an organic EL element (hereinafter referred to as an organic EL display device) usually has the configuration shown in FIG. 9. In this configuration, a plurality of organic EL elements, each having an organic compound layer sandwiched between a pair of electrodes, are arranged on a substrate, in which a driving circuit is provided, with the surface covered by a protection member. On a substrate 1 in which the driving circuit not shown is provided, the following are provided: a bottom electrode 2, an element separation film 3 that covers the end of the bottom electrode 2 and delimits the light emitting region of the organic EL element, an organic compound layer 4 that includes at least a light emitting layer provided on the bottom electrode 2, and a top electrode 5 provided on the organic compound layer 4. The organic EL element described here refers to the structure including the bottom electrode 2, the top electrode 5, and the organic compound layer 4 sandwiched between those electrodes. The organic EL element is covered with a protecting layer 6 to protect against deterioration of the organic EL element from moisture and oxygen included in an exterior space 15.

However, in the configuration illustrated in FIG. 9, emitting lights emitted from the organic EL elements to various angles are totally reflected primarily at the boundary between the protecting layer 6 and the exterior space 15. This generates a problem that half or more of the emitting lights cannot be output outside the organic EL display device.

To address this problem, Japanese Patent Application Laid-Open No. 2004-039500 discusses the structure in which the micro lens array of resin material is provided on the surface of the organic EL elements covered with the protecting layer. This configuration reduces the total reflection generated at the boundary between the display device and the exterior space, allowing the emitting light to be output efficiently into the exterior space, especially, into the front direction (into the normal line direction of the substrate surface).

In an environment in which light (external light) is received from an external source, especially, in an environment in which external light is strong such as an outdoor environment, external light entering a display device reflects in the display device and output back to the outside of the display device. In this case, an observer observes a light generated by adding the external light reflected in the display device to the emitting light, and feels that the visibility (contrast, view angle characteristics, etc.,) is decreased. To improve the decreased visibility, a method is known in which a circularly polarized light member is provided on the light output side of the display device, in other words, on the light emission surface side of the light emitting element array, to extinct the external light reflected in the display device (hereinafter called an external light reflection).

A circularly polarized light member has a property that the extinction degree of external light is high when the external light vertically enters the surface of the circularly polarized light member and reflects (in other words, the extinction degree of external light reflection) but is low when the external light obliquely enters and reflects. The extinction degree refers to the ratio of the light components, which do not transmit through the circularly polarized light member, to the external light reflection that enters the circularly polarized light member.

This property of a circularly polarized light member prevents an external light reflection from being fully reduced even if a circularly polarized light member is provided on a display device on which a micro lens array, such as the one discussed in Japanese Patent Application Laid-Open No. 2004-039500, is provided. This is because concavo-convex shape of the surface of the micro lens array provided on the surface of the light emitting elements causes external light to be reflected irregularly in various directions, which increases the ratio of the external light reflection that obliquely enters the circularly polarized light member. Therefore, the display device, on which the micro lens is provided, cannot fully extinct the external light reflection only with the circularly polarized light member, leaving room for improvement to ensure good visibility.

### SUMMARY OF THE INVENTION

The present invention is directed, among other things, to a display device that has a micro lens to increase the light output efficiency wherein, to ensure higher visibility, the display device reduces an external light reflection that is caused by the concavo-convex shape of the micro lens and cannot achieve enough extinction even if a circularly polarized light member is provided.

According to an aspect of the present invention, a display device including a light emitting element array composed of a plurality of light emitting elements comprises a micro lens array composed of a plurality of micro lenses provided on a light emission surface side of the light emitting element array and a light shielding member provided on the light emission surface side more than the micro lens array, wherein the light shielding member includes a light shielding member in which a light absorption wall and a medium arranged alternately along the light emission surface, a light absorption rate of the medium being lower than a light absorption rate of the light absorption wall.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIG. 1 is a general cross sectional view illustrating a display device in a first exemplary embodiment of the present invention.

FIGS. 2A and 2B are diagrams illustrating the path of external light that enters a display device having micro lenses.

FIG. 3 is a diagram illustrating an example of the reflectance-to-angle characteristics of a circularly polarized light member.

FIG. 4 is a diagram illustrating the configuration of a light shielding member.

FIG. 5 is a diagram illustrating how the transmittance of the light shielding member depends on the angle.

FIGS. 6A and 6B are diagrams illustrating the light shielding member used in the present invention.

FIG. 7 is a general cross sectional view illustrating a display device in a second exemplary embodiment.

FIG. 8 is a block diagram illustrating a video information processing device in which the display device of the present invention is used.

FIG. 9 is a general cross sectional view illustrating a conventional display device.

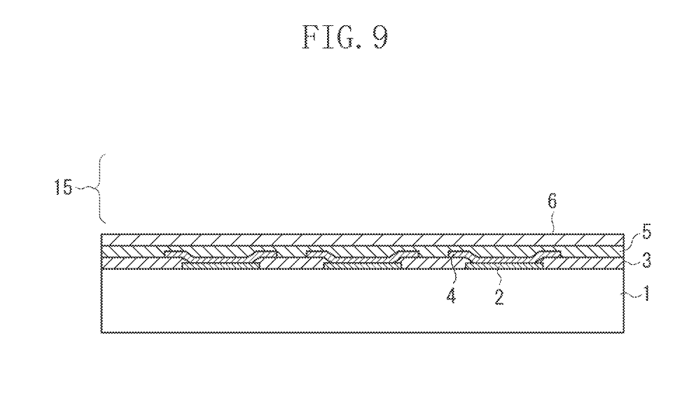

### DESCRIPTION OF THE EMBODIMENTS

Various exemplary embodiments, features, and aspects of the invention will be described in detail below with reference to the drawings.

The following describes a display device of the present invention with reference to the drawings. Although an organic EL display device is used as an example in the description below, the light emitting element of the display device of the present invention is not limited to an organic EL element but is applicable to a light emitting element such as an inorganic EL element and a light emitting diode (LED).

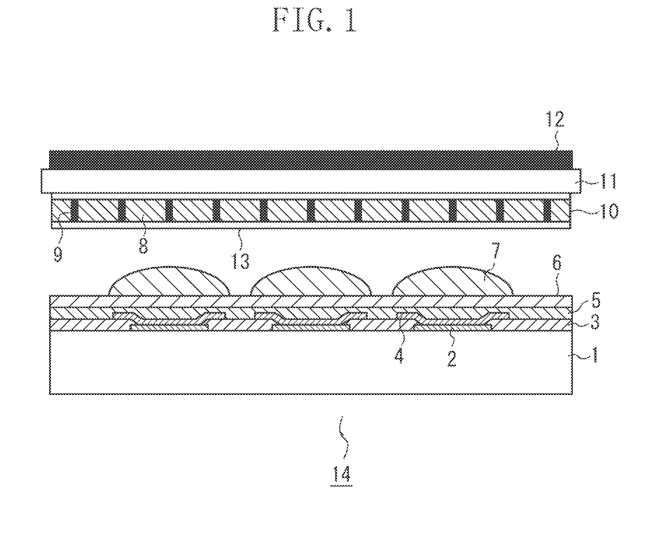

The following descries a first exemplary embodiment. FIG. 1 is a general cross sectional view illustrating a display device in the first exemplary embodiment of the present invention. A display device 14 is a top emission type display device that outputs light in the direction opposite to a substrate 1 (in the direction of the top of the figure). On the substrate 1 in which a driving circuit not shown is provided, a bottom electrode 2, an organic compound layer 4, and a top electrode 5 are provided in this order, and a light emitting element array is configured with a plurality of light emitting elements. The bottom electrode 2 is provided with being divided according to the size of the light emitting element.

The organic compound layer 4, a laminated body composed of a single layer or a plurality of layers including a light emitting layer, may include not only the light emitting layer but also functional layers such as a hole transport layer, an electron transport layer, and an electron injection layer. The organic compound layer 4 may be configured by any known material. The organic compound layer 4, usually a thin layer several tens of nm in thickness, cannot cover the film-thickness level difference at the end of the bottom electrode 2, sometimes with the result that the organic EL element does not emit light because of a short between the top electrode 5, which is formed afterward, and the bottom electrode 2. In such a case, an element separation layer 3 covering the end of the bottom electrode 2 may be provided. On the organic compound layer 4 is provided the top electrode 5 that extends across a plurality of light emitting elements. Note that a light emitting element (organic EL element) refers to the structure composed of the bottom electrode 2, top electrode 5, and the organic compound layer 4 sandwiched between the bottom electrode 2 and the top electrode 5.

Although, in FIG. 1, the bottom electrode 2 is provided for each light emitting element and the top electrode 5 is provided continuously across a plurality of light emitting elements so that the top electrode 5 acts as the common electrode of the light emitting element array, the present invention is not limited to this configuration if the display device is configured to enable each light emitting element to be driven. One of the electrodes, bottom electrode 2 or top electrode 5, on the light output side, in other words, the electrode disposed on the light emission surface side, is formed by a film through which light transmits, such as an indium tin oxide (ITO) film, an indium-doped zinc oxide (InZnO) film, or a thin metal about several nm in thickness. The other electrode can be a reflective electrode so that the emitted light is reflected and output to the light emission surface side. More specifically, a single-layer electrode of highly reflective metal or a laminated-layer electrode, composed of a metal layer and a transparent conductive layer of ITO or InZnO, can be used.

A protection film 6 is provided on the top electrode 5 to prevent moisture or oxygen from entering the light emitting elements. In addition, a micro lens 7 is provided on each of the light emitting elements. The protection film 6 can be an insulating material with high moisture resistance and high light transmittance. In particular, a silicon nitride film or a silicon oxide film may be advantageously used for the protecting film 6. The micro lens 7 is formed by fabricating from resin or inorganic materials. For example, a resin material formed to uniform thickness can be formed into a lens shape by embossing or by the photolithographic patterning method in which the resin material is exposed to light having distribution in an in-plane direction. Although the micro lens 7 is provided for each light emitting element in FIG. 1, the positional relation between the micro lens 7 and a light emitting element is not limited to this relation. For example, it is possible that the micro lens 7 is not provided on all organic EL elements, that one micro lens 7 is provided for a plurality of light emitting elements, or that a plurality of micro lenses 7 is provided for one light emitting element. In the description below, a plurality of micro lenses 7 is sometimes called collectively a micro lens array.

A light shielding member 10 is provided above the micro lens array on the light emission surface side (observer side). The light shielding member 10 is a member composed of an alternation of a light absorption wall 9 and a medium 8 wherein the light absorption wall 9 absorbs light entering the substrate surface from an angle. The light absorption walls 9 are arranged so as to line up along the light emission surface (in other words, the substrate surface) of the display device. The light shielding member 10 will be described in detail later. A circularly polarized light member 12 is provided still nearer to the observer side than the light shielding member 10. As the circularly polarized light member 12, a known member that is a combination of a linear polarization plate and a ¼ phase difference plate may be used.

In FIG. 1, the light shielding member 10 and the circularly polarized light member 12 are arranged with sandwiching a supporting plate 11 between them. The supporting plate 11 is a plate that supports the film-like light shielding member 10 and the circularly polarized light member 12 so that they are parallel to the substrate 1. Therefore, the supporting plate 11 need not be provided if the light shielding member 10 and the circularly polarized light member 12 can be supported parallel to the substrate 1 with some other method. For example, one possible method is that the concave portions of the micro lens array are filled by a filling layer to make the surface flat and, on that flat surface, the light shielding member 10 and the circularly polarized light member 12 are arranged. For example, the filling layer used in this case is a high light transmittance material having a refractive index lower than that of the material of the micro lens array. The difference between the refractive index of the filling layer and that of the micro lens array can be equal to or larger than 0.3.

The following describes the operation of the light shielding member 10, followed by the description of its configuration.

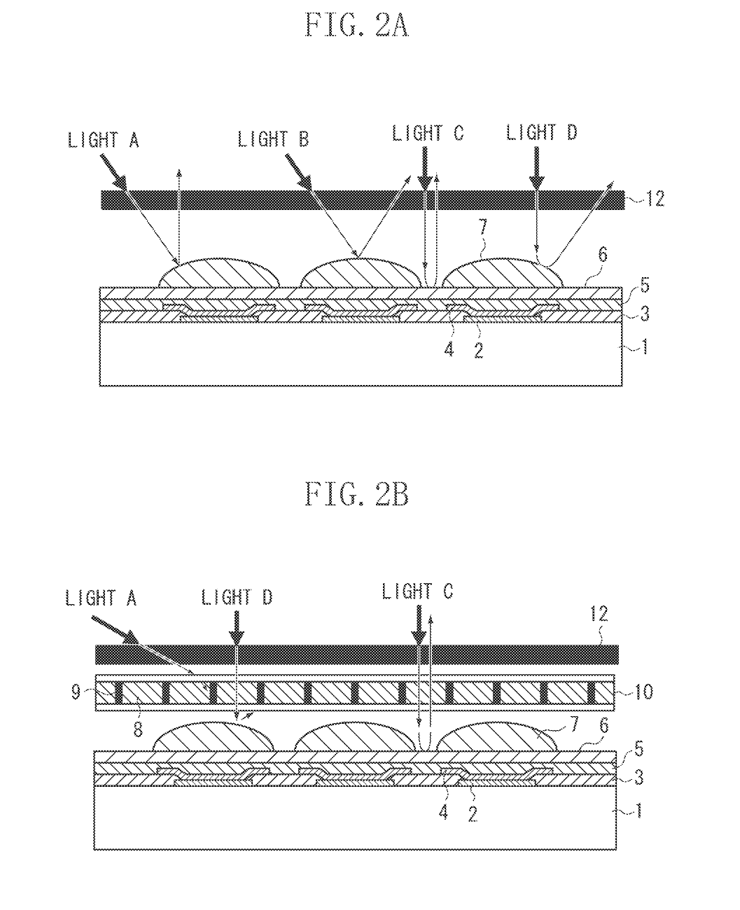

First, with reference to FIG. 2A, the following describes the reflection of external light when only the circularly polarized light member 12 is provided on a display device on which the micro lens array is provided. Light A is a light that obliquely enters the surface of the substrate (hereinafter simply referred to as “obliquely”) and reflects vertically to the surface of the substrate (hereinafter referred to as simply “vertically”). Light B is a light that enters obliquely and reflects obliquely. Light C is a light that enters vertically and reflects vertically. Light D is a light that enters vertically and reflects obliquely. On a display device on which the micro lens array is not provided, the reflection surface is flat and so, usually, a light such as light A or D is not generated. On the other hand, on the display device of the present invention external light reflects on the surface of the micro lens, so that a light such as light A or light D is generated in many cases.

Now, consider the visibility when an observer observes the display device from the front direction (from the direction vertical to the surface of the substrate). A part of external light, which enters the display device at various angles, reflects in the front direction on the surface of the micro lens and becomes light A. Light A passes through the circularly polarized light member 12 when entering the display device, has the amount of light reduced by about half and, at the same time, becomes a clockwise (or counterclockwise) circularly polarized light. However, light A that obliquely enters the circularly polarized light member 12 includes light components that do not become a circularly polarized light. After that, the circularly polarized light reflects in the display device, becomes a counterclockwise (or clockwise) circularly polarized light, and is absorbed when the light passes the circularly polarized light member 12 again. In this case, the light components that do not become a circularly polarized light are not absorbed but passes through the circularly polarized light member 12. As a result, sufficient extinction of external light cannot be achieved only by the circularly polarized light member 12 and, therefore, high visibility cannot be achieved. The same phenomenon occurs with light D. Light B that is not output in the front direction does not affect the observation from the front direction. Light C that vertically enters the circularly polarized light member 12 does not include light components that do not become a circularly polarized light and, therefore, sufficient extinction can be achieved only by the circularly polarized light member 12. In other words, on the display device illustrated in FIG. 2A, the lights that may adversely affect the visibility are light A and light D.

Next, the following describes the reflection of external light when the light shielding member 10 and the circularly polarized light member 12 are provided on the display device on which the micro lens array is provided. FIG. 2B illustrates the path of light that enters the display device from an external source and reflects on the surface of the display device. A part of light A that obliquely enters the display device and traverses the light absorption wall 9 of the light shielding member 10 is absorbed and, therefore, does not reach the display device. Light C that vertically enters the display device becomes a circularly polarized light when the light passes through the circularly polarized light member 12 and passes through the medium 8. This circularly polarized light reflects vertically in the display device, becomes a reverse-direction polarized light, passes through the medium 8 again, and is absorbed when the light passes through the circularly polarized light member 12. Light D that vertically enters the display device becomes a circularly polarized light when the light passes through the circularly polarized light member 12 and transmits through the medium 8. This circularly polarized light becomes a reverse-direction polarized light when the light reflects obliquely on the light emitting element but does not reach the circularly polarized light member 12, because the light is absorbed by the light absorption wall 9. Therefore, light A and light D, which cannot be achieved sufficient extinction by the circularly polarized light member 12, are absorbed by the light shielding member 10, meaning that the visibility that is decreased in FIG. 2A is not decreased.

Next, the following describes the configuration of the light shielding member 10. The light shielding member 10 is composed by alternately arranging the light absorption wall 9 and a medium having a light absorption rate lower than that of the light absorption wall 9. The light shielding member 10 is sandwiched between base material films 13 as necessary. The light absorption walls 9 are a fixed at predetermined pitch. The medium 8 can be fabricated using a material with a low light-absorption rate in a visible-light range 10% or lower, and more usefully 5% or lower. Silicon resin can be useful for the material of the medium 8. The light absorption wall 9 can be fabricated using a material with a high light-absorption rate in a visible-light range 90% or higher, and more usefully 95% or higher. The material of the light absorption wall 9 can be silicon resin that is colored black or near-black by mixing the resin with a coloring agent such as carbon fine particles. To efficiently output the emitting light outside the display device, the width of the light absorption wall 9 in the array direction can be smaller than that of the medium 8 in the array direction. As the base material film 13, an optically isotropic, transparent material having the refractive index approximately equal to that of the medium 8 is used to prevent the polarization characteristics from being affected.

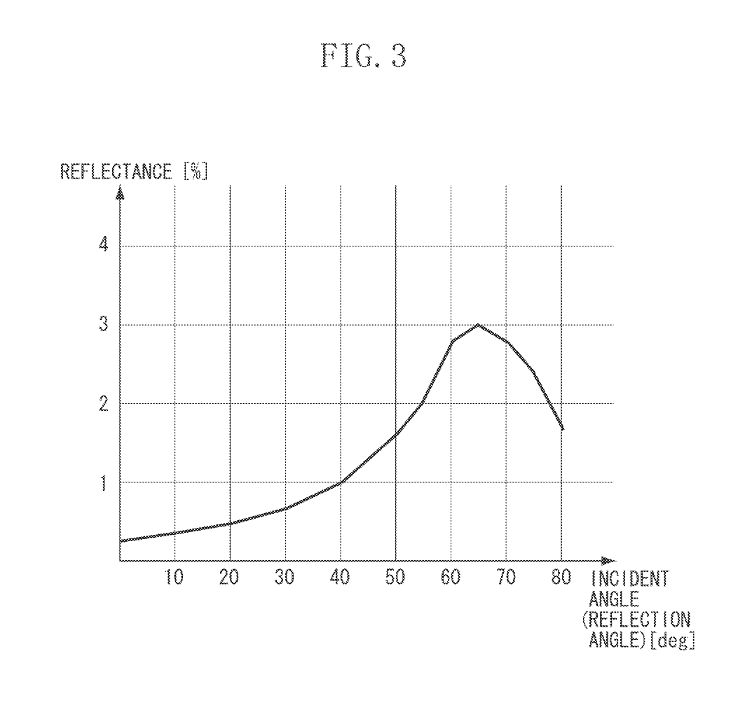

The light absorption wall 9 illustrated in FIG. 1 and FIG. 3 is alternately arranged with the mediums 8 at a fixed pitch that is ⅓ of the pitch of the light emitting element. If the pitch of the light absorption walls 9 is greater than the pitch of the light emitting element, there is no corresponding light absorption wall 9 for one light emitting element. This means there is an area where light A or light B cannot be shielded. Therefore, the pitch of the light absorption wall 9 can be smaller than the pitch of the light emitting element. In addition, to prevent moire from being generated, it is desirable that the pitch of the light absorption wall 9 is 1/x (x is a natural number) of the pitch of the light emitting element, in other words, the pitch of the light emitting element is a multiple of a natural number representing the pitch of the light absorption wall 9.

The larger the value of (T/L) is, the higher the oblique-light absorption performance is, where L is the pitch of the light absorption wall 9 and T is the height of the light absorption wall 9. However, note that the width of the light absorption wall 9 is so small that the brightness of the display device remains almost constant when the display device is observed from the front but decreases when the display device is observed from an angle. In other words, the view angle becomes narrow. Therefore, (T/L) should be determined according to the view angle design of the display device.

FIG. 3 shows an example of the reflectance-to-angle characteristics of the structure in which the circularly polarized light member is placed on the flat reflection surface. The horizontal axis indicates the incident angle (=reflection angle) of light, in other words, the angle between the normal line to the reflection surface and the incident light, and the vertical axis indicates the reflectance. The reflectance in FIG. 3 indicates the ratio of the light, which is reflected on the reflection surface, passes through the circularly polarized light member again, and is output, to the light that enters the circularly polarized light member. FIG. 3 indicates that the greater the incident angle of the light entering the circularly polarized light member is, the greater the reflectance is. The reflectance reaches the maximum of about 3% when the incident angle of the light is about 65 degrees.

In general, the visibility of a display device is evaluated by observing the display device from the front. On a flat reflection surface, the light that enters obliquely is reflected at the angle equal to the incident angle. Therefore, the observer observes a reflected light when the angle of the line of sight of the observer is almost equal to the angle of the incident light. The visibility is assumed good when the reflectance is about 1% or lower. In the case of FIG. 3, the display device is good for observation in the range of the incident angle from 0° to about 40°, in other words, in the range from 0° to about 40° with respect to the front.

However, on a display device on which the micro lens array is provided, external light irregularly reflects on the surface of the micro lens 7. Therefore, as indicated by light A in FIG. 2A, the light that enters from an angle reflects in the front direction, sometimes affecting the observation from the front. Consequently, it is necessary to reduce the light of the incident angle of about 65°, where the reflectance is high, to about 1%.

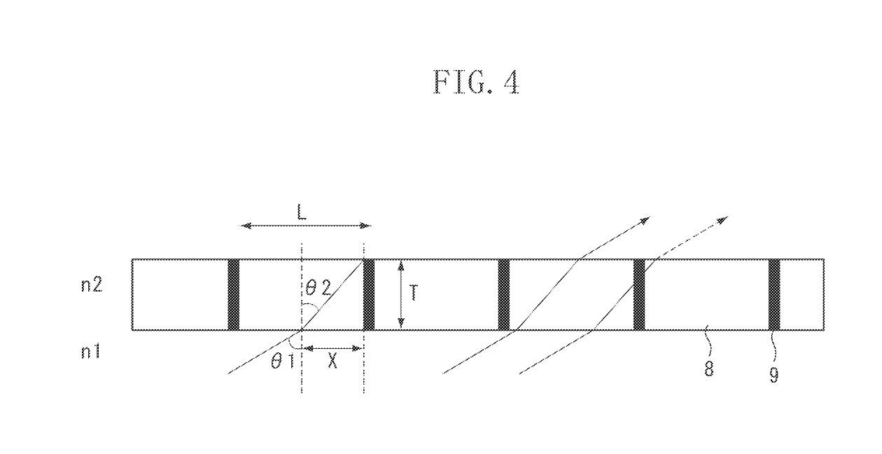

Now, consider the configuration of the light shielding member for reducing the light of the incident angle of 65°, where the reflectance is high, to about 1%. To reduce the reflectance of the light of the incident angle of about 65° from 3% to 1%, the amount of light of the incident angle of 65° that enters the circularly polarized light member should be reduced by ⅔. To do so, the expressions given below are derived from FIG. 4. Where n₁ is the refractive index of space through which the incident light travels, n₂ is the refractive index of the light shielding member, θ₁ is the incident angle of light that enters the light shielding member, and θ₂ is the angle of refraction of the light in the light shielding member.

X/L≧⅔ (1)

X=T tan θ₂ (2)

From Snell's law, the following expression is obtained.

n₁ sin θ₁=n₂ sin θ₂ (3)

Assuming that the incident light travels through air, expression (3) is changed as follows by substituting n₁=1.0 and θ₁=65° in expression (3).

sin θ₂=0.906/n₂ (3)′

Here, because tan θ=sin θ/{1−(sin θ)²}^{0.5}, expressions (1) and (2) can be changed as follows.

T sin θ₂/{1−(sin θ₂)²}^{0.5}/L≧⅔T/L≧⅔{1−(sin θ₂)²}^{0.5}/sin θ₂

By substituting expression (3)′ in this expression, the following is obtained.

T/L≧⅔{(n₂)²−0.821}^{0.5}/0.906=0.736{(n₂)²−0.821}^{0.5} (4)

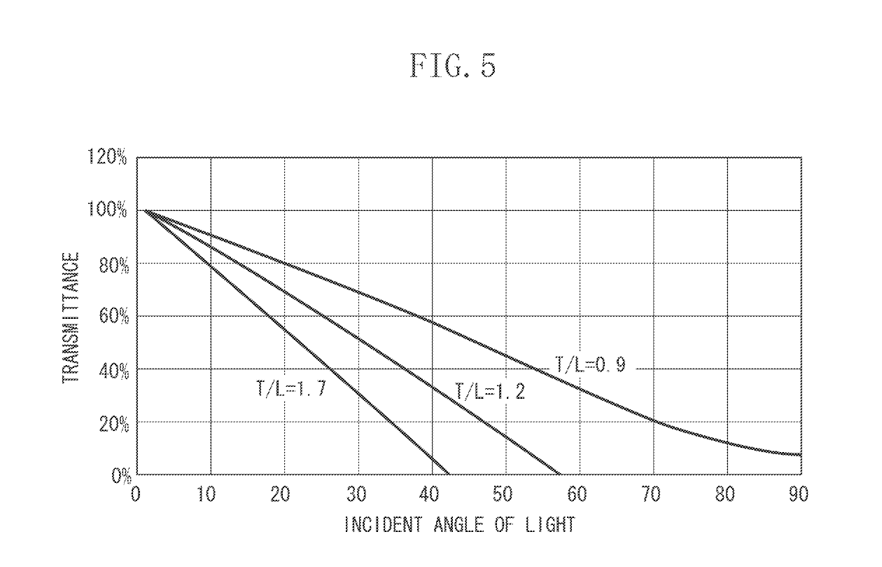

For example, when the refractive index of the medium 8 of the light shielding member 10 is 1.5 (in other words, n₂=1.5), it is clear from expression (4) that the relation between the arrangement pitch L and the height T of the light absorption wall 9 can be T/L≧0.9. For reference, FIG. 5 shows the relation between T/L and the transmittance and the incident angle of light when n₂=1.5.

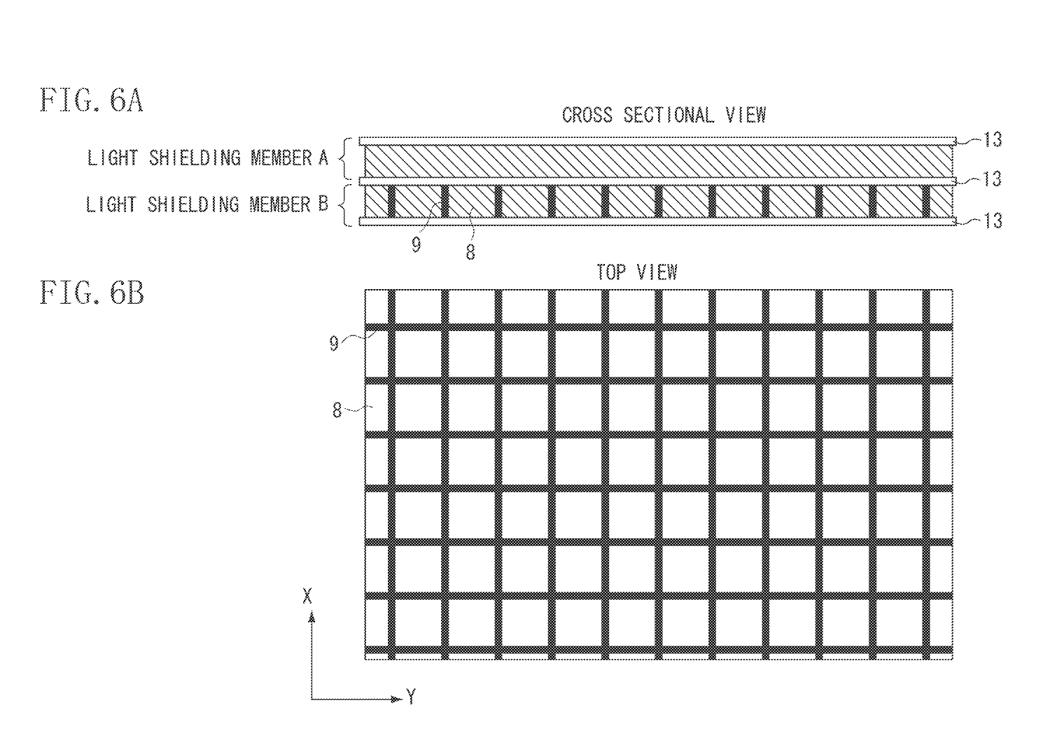

A plurality of light shielding members 10 may be used by combining a plurality of pieces as shown in FIGS. 6A and 6B. The light shielding member 10 illustrated in FIGS. 6A and 6B has a structure in which light shielding member A, which includes light absorption walls arranged in the X direction, and light shielding member B, which includes light absorption walls arranged in the Y direction, are laminated. Each of light shielding members A and B is sandwiched between the base material film 13 that is optically isotropic. Similarly, in this structure, T/L can be determined so that each of light shielding members A and B satisfies expression (4). In addition, although the light absorption walls of light shielding members A and B are at right angles to each other in FIGS. 6A and 6B, the crossing angle may be changed according to the design.

As described above, the display device according to the exemplary embodiment of the present invention provides the light shielding member 10 that absorbs external light that obliquely enters the display device. This configuration reduces external light reflection generated by the irregular reflection on the surface of the micro lens array, thus providing a display device that is superior in visibility.

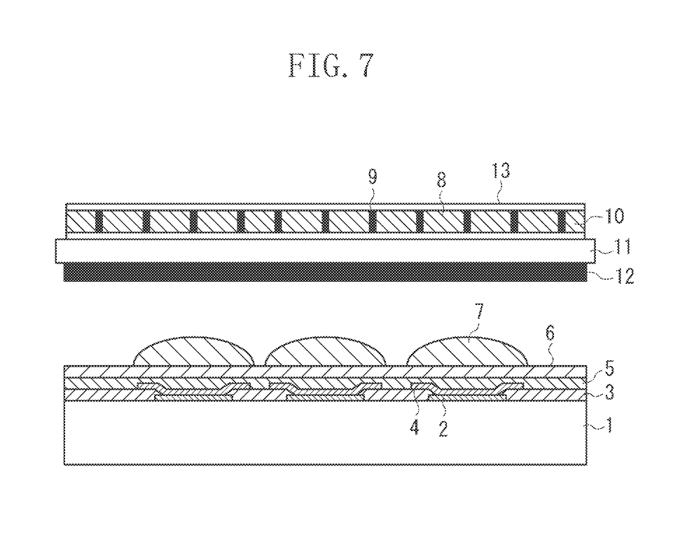

The following describes a second exemplary embodiment. FIG. 7 is a general cross sectional view illustrating a display device in the second exemplary embodiment of the present invention. In the first exemplary embodiment, the sheet-like light shielding member 10 is provided between the sheet-like circularly polarized light member 12 and the micro lens array, all in parallel to each other. In the second exemplary embodiment, the circularly polarized light member 12 is provided between the light shielding member 10 and the micro lens array.

In this exemplary embodiment, the light shielding member 10 is provided outer than the circularly polarized light member 12, so that the light shielding member 10 does not affect the polarization characteristics. This eliminates the need for the base material film 13 to be optically isotropic. An optically anisotropic film, for example, a stretched polycarbonate (refractive index 1.5) film, may be used for the base material film 13 of the light shielding member 10. In this case, to reduce the reflection in the interface between the light shielding member 10 and the base material film 13, it is desirable that the light shielding member 10 and the base material film 13 have an equal refractive index. When stretched polycarbonate is used for the base material film 13, silicon resin of high refractive index (refractive index 1.5) can be used for the medium 8 of the light shielding member 10. In this exemplary embodiment, similarly to the first exemplary embodiment, the light shielding member 10, combining two light shielding members A and B illustrated in FIGS. 6A and 6B, may be used.

The organic EL display device fabricated in this way can reduce external light reflection and a display device high in display quality can be acquired, similarly to the first exemplary embodiment.

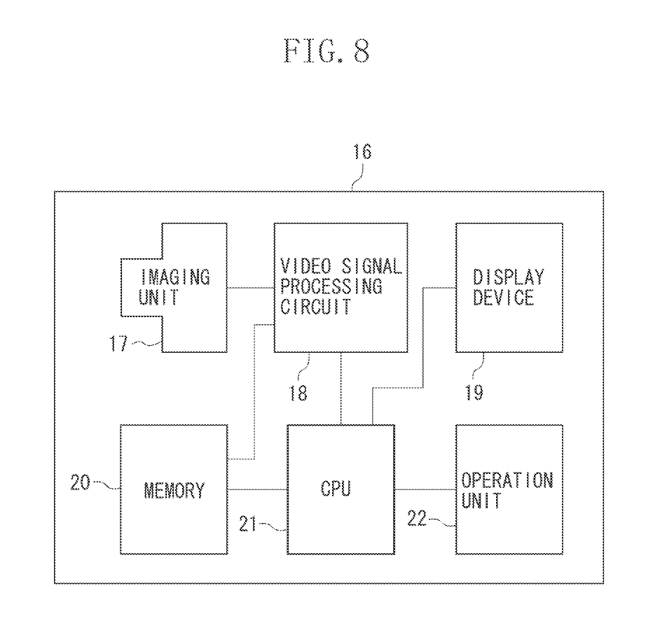

The following describes a third exemplary embodiment. This exemplary embodiment shows an example in which the display device in the first and second exemplary embodiments is used for a video information processing device. FIG. 8 is a block diagram illustrating a digital still camera system used as a video information processing device to which the present invention is applied. Referring to the figure, a digital still camera system 16 includes an imaging unit 17, a video signal processing circuit 18, a display device 19 of the present invention, a memory 20, a central processing unit (CPU) 21, and an operation unit 22.

In FIG. 8, a video imaged by the imaging unit 17 or video information recorded in the memory 20 is processed into signals by the video signal processing circuit 18 to generate a video signal that is displayed on the display device 19. A controller has the CPU 21 that controls the imaging unit 17, memory 20, and video signal processing circuit 18 in response to an input from the operation unit 22 to perform imaging, recording, reproducing, or displaying operation according to the situation. The display device 19 may also be used as the display unit of various video information processing devices, and is ideal for use as a mobile electronic apparatus usually used outdoors.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Application No. 2010-261605 filed Nov. 24, 2010, which is hereby incorporated by reference herein in its entirety.

What is claimed is:

1. A display device including a light emitting element array composed of a plurality of light emitting elements, the display device comprising:
a micro lens array composed of a plurality of micro lenses provided on a light emission surface side of the light emitting element array; and
a light shielding member provided on the light emission surface side more than the micro lens array,
wherein the light shielding member includes a light absorption wall and a medium arranged alternately along the light emission surface, a light absorption rate of the medium being lower than a light absorption rate of the light absorption wall.

2. The display device according to claim 1, further comprising:
a circularly polarized light member disposed on at least one of the light emitting element array side of the micro lens array and a side opposite to the light emitting element array.

3. The display device according to claim 1, wherein
the light absorption walls are arranged at a fixed pitch and
wherein a pitch of the light emitting elements is a natural number multiple of the fixed pitch.

4. The display device according to claim 1, wherein the light shielding member satisfies
T/L≧0.736(n²−0.821)^{0.5},
where L is the pitch of the plurality of light absorption walls, T is a height of the plurality of light absorption walls, and n is a refractive index of the medium.

5. A video information processing device comprising:
a memory configured to record video information;
a video signal processing circuit configured to perform signal processing of the video information for generating a video signal;
the display device according to claim 1, wherein the display device is configured to display a video in response to the video signal; and
a CPU configured to control the video signal processing circuit and the display device.
